(19) United States
(12) Patent Application Publication
(10) Pub. No.: US 2004/0104043 A1
(43) Pub. Date: Jun. 3, 2004

(54) Circuit device and method of manufacturing the same

(76) Inventors: Noriyasu Sakai, Gunma (JP); Yusuke Igarashi, Gunma (JP)

Correspondence Address: FISH & RICHARDSON P.C., 45 ROCKEFELLER PLAZA, SUITE 2800, NEW YORK, NY, 10111, US

(21) Appl. No.: 10/667,046

(22) Filed: Sep. 22, 2003

(30) Foreign Application Priority Data
Sep. 27, 2002 (JP) P.2002-284033

(51) Int. Cl. H05K 3/28

(52) U.S. Cl. 174/260; 257/730; 257/787; 438/126; 29/841

(57) ABSTRACT

The present invention discloses a method of manufacturing circuit devices 10 with arbitrary external shapes, comprising the steps of: forming, on a conductive foil 30, conductive patterns 11 constituting circuit devices 10 of the same type or different types; affixing circuit elements 12 onto conductive patterns 11; molding with insulating resin 13 so as to cover circuit elements 12; and using a laser to cut insulating resin 13 at locations of the outer peripheral part of each circuit device 10 that are in accordance with a desired shape to thereby perform separation into each of circuit devices 10. Circuit devices 10 with arbitrary shapes can thus be manufactured and circuit devices that accommodate the shapes of the frames of sets can be provided.

### BACKGROUND OF THE INVENTION

1. Field of the Invention

This invention concerns a thin circuit device having an arbitrary outer peripheral shape and a method of manufacturing such a circuit device.

2. Description of the Related Art

Compactness, low profile, and light-weight properties have been demanded in conventional circuit devices set in electronic equipment as they are employed in portable telephones, portable computers, etc. With regard to semiconductor devices that are circuit devices, a package type semiconductor sealed by normal transfer molding can be cited as a general, prior-art type of semiconductor device. This type of semiconductor device is mounted onto a printed substrate PS as shown in FIG. 31.

Also with this package type semiconductor device 61, a semiconductor chip 62 is covered with a resin layer 63 and lead terminals 64 for external connection are lead out from side parts of this resin layer 63. However, this package type semiconductor device 61 has lead terminals 64 extending out of resin layer 63, and does not satisfy the requirements of compactness, low-profile, and light-weight. Various firms have competed in developing various structures to realize compact, low profile, and light-weight devices, and recently, devices called CSP's (chip size packages), such as wafer-scale CSP's with a size equivalent to the size of a chip and CSP's with a size slightly larger than a chip size have been developed.

FIG. 32 shows a CSP 66 with a size slightly larger than a chip size and employs a glass epoxy substrate 65 as the supporting substrate. Here, a description shall be provided for a case where a transistor chip T is mounted onto glass epoxy substrate 65.

On the top surface of this glass epoxy substrate 65 are formed a first electrode 67, a second electrode 68, and a die pad 69, and on the rear surface are formed a first rear surface electrode 70 and a second rear surface electrode 71. Via through-holes TH, the abovementioned first electrode 67 is electrically connected with first rear surface electrode 70 and second electrode 68 is electrically connected with second rear surface electrode 71. The abovementioned bare transistor chip T is affixed onto die pad 69. The emitter electrode of the transistor is connected via a metal wire 72 to first electrode 67 and the base electrode of the transistor is connected via a metal wire 72 to second electrode 68. Furthermore, a resin layer 73 is provided on glass epoxy substrate 65 so as to cover transistor chip T.

Though employing a glass epoxy substrate 65, the above-described CSP 66, unlike a wafer-scale CSP, has the merits of being simple in the extension structure from chip T to the rear surface electrodes 70 and 71 for external connection and being inexpensive to manufacture. The above-described CSP 66 is mounted onto a printed substrate PS as shown in FIG. 31. Printed substrate PS is provided with electrodes and wiring for forming an electrical circuit, and the above-described CSP 66, a package type semiconductor device 61, a chip resistor CR, a chip capacitor CC, etc., are electrically connected and affixed thereon. Circuits formed on such a printed substrate have been mounted in various sets.

However, the above-described circuit devices and printed substrates onto which such circuit devices are mounted had the following problems.

Firstly, since CSP 66 is formed with glass epoxy substrate 65 as a supporting base and glass epoxy substrate 65 in itself is a thick material, there was a limit to making CSP 66 thin.

Secondly, since printed substrate PS has a function of mechanically supporting the mounted CSP 66, etc., it is made thick in order to maintain mechanical strength. This impeded the low profiling of portable telephones and other sets in which a printed substrate PS is built in.

Thirdly, since the above-described CSP 66 is separated individually by dicing, its planar shape is formed to be rectangular. Thus when CSP 66 is directly affixed inside a frame of a set with a shape other than rectangular, it becomes difficult to make effective use of the space inside the frame.

Fourthly, in a case where a circuit device of a type where a plurality of passive elements, active elements, and other circuit elements are sealed in resin is realized in the same arrangement as CSP 66, a large amount of resin for sealing becomes necessary since the respective circuit elements differ in size.

This invention has been made in view of such problems, and a main object of this invention is to provide a circuit device, with which the external shape can be formed to an arbitrary shape to enable direct mounting in the interior of a frame of a set, etc., and a manufacturing method of such a circuit device.

### SUMMARY OF THE INVENTION

One of the objects of the present invention is to provide a circuit device comprising: circuit elements; conductive patterns, to which the circuit elements are affixed and forming wiring; and an insulating resin, sealing the circuit elements and the conductive patterns; and in that side face of the insulating resin is cut by a laser.

Preferably, an outer peripheral part formed of the insulating resin is curved.

Preferably, corner parts of an outer peripheral part formed of the insulating resin are formed to an acute angle or an obtuse angle.

One of the objects of the present invention is to provide a method comprising the steps of: forming, on a conductive foil, conductive patterns constituting circuit devices of the same type or different types; affixing circuit elements onto the conductive patterns; molding with insulating resin so as to cover the circuit elements; and using a laser to cut the insulating resin at locations of the outer peripheral part of each circuit device that are in accordance with a desired shape to thereby perform separation into each of the circuit devices.

One of the objects of the present invention is to provide method comprising the steps of: forming separation grooves, which are shallower than the thickness of the conductive foil, at regions of the conductive foil except for regions that are to be conductive patterns constituting circuit devices of the same type or different types; affixing circuit elements onto the conductive patterns; molding with insulating resin so as to cover the circuit elements and fill the separation grooves; removing the rear surface of the conductive foil until the insulating resin is exposed; and using a laser to cut the insulating resin at locations of the outer peripheral part of each circuit device that are in accordance with a desired shape to thereby perform separation into each of the circuit devices.

Preferably, the laser is used to remove only the insulating resin.

Preferably, a carbon dioxide laser is used to remove the insulating resin.

Preferably, the conductive patterns form die pads, bonding pads, and wiring.

Preferably, an outer peripheral part formed of the insulating resin is formed in a curving manner.

Preferably, corner parts of an outer peripheral part formed of the insulating resin are formed to an acute angle or an obtuse angle.

One of the objects of the present invention is to provide a method comprising the steps of: forming conductive patterns constituting at least one circuit device on regions of a conductive foil; affixing circuit elements onto the conductive patterns; molding with insulating resin so as to cover the circuit elements; forming through-holes in the insulating resin; and separating into individual circuit devices.

One of the objects of the present invention is to provide a method comprising the steps of: forming separation grooves, which are shallower than the thickness of the conductive foil, at regions of the conductive foil except for regions that are to be conductive patterns constituting at least one circuit device; affixing circuit elements onto the conductive patterns; molding with insulating resin so as to cover the circuit elements and fill the separation grooves; forming through-holes in the insulating resin so as to partially expose the separation grooves; removing the remaining thickness portions of the conductive foil at locations at which the separation grooves are formed to expose the insulating resin filled in the separation groove and the through-holes; and separating into individual circuit devices.

Preferably, a laser is used to form the through-holes.

Preferably, the laser is reflected by the surfaces of the separation grooves and the side faces of the through-holes are formed vertically.

One of the objects of the present invention is to provide a method of manufacturing a circuit device with which a plurality of external electrodes formed of brazing material are formed on a rear surface, the height of the external electrodes are made uniform by irradiation of a laser in the surface direction of the circuit device.

This invention provides the following effects.

Firstly, since a laser is used to separate circuit devices 10, circuit devices having arbitrary external shapes can be manufactured. Circuit devices accommodating the interior of the frames of portable telephones and other sets can thus be manufactured. Furthermore, since the laser cuts only insulating resin 13, damaging of the circuit elements due to the heat generated by the use of the laser can be prevented.

Secondly, whereas with the prior-art, semiconductor elements 12A and other circuit elements were mounted onto a printed substrate, with the present invention, since circuit device 10 itself takes the form of a substrate that incorporates a circuit element, circuit device 10 can be mounted in the interior of the frame of a set. Furthermore, since the printed substrate of the prior art becomes unnecessary, a light-weight device can be realized.

Thirdly, through-holes 15, the side faces of which are formed vertically, can be formed by the use of a laser, and these through-holes 15 can be used as machine screw holes, etc.

Fourthly, since external electrodes 19 can be made uniform in height in the thickness direction, electrical connection of external electrodes 9 with the exterior can be assured.

Fifthly, since the outer shape of the device can be formed along the shape of the electrical circuit that comprises the circuit elements and the conductive patterns, the amount of insulating resin used for sealing can be reduced.

### BRIEF DESCRIPTION OF THE DRAWINGS

FIG. 1(A) is a plan view, FIG. 1(B) is a sectional view, and FIG. 1(C) is a sectional view for describing this invention's circuit device.

FIG. 2 is a sectional view for describing a method of manufacturing this invention's circuit device.

FIG. 3 is a sectional view for describing a method of manufacturing this invention's circuit device.

FIG. 4(A) is a sectional view and FIG. 4(B) is a plan view for describing a method of manufacturing this invention's circuit device.

FIG. 5(A) is a sectional view and FIG. 5(B) is a plan view for describing a method of manufacturing this invention's circuit device.

FIG. 6(A) is a sectional view and FIG. 6(B) is a plan view for describing a method of manufacturing this invention's circuit device.

FIG. 7 is a sectional view for describing a method of manufacturing this invention's circuit device.

FIG. 8 is a sectional view for describing a method of manufacturing this invention's circuit device.

FIG. 9 is a sectional view for describing a method of manufacturing this invention's circuit device.

FIG. 10(A) is a sectional view and FIG. 10(B) is a plan view for describing a method of manufacturing this invention's circuit device.

FIG. 11(A) is a plan view, FIG. 11(B) is a sectional view, and FIG. 11(C) is a sectional view for describing this invention's circuit device.

FIG. 12 is a sectional view for describing a method of manufacturing this invention's circuit device.

FIG. 13 is a sectional view for describing a method of manufacturing this invention's circuit device.

FIG. 14 is a sectional view for describing a method of manufacturing this invention's circuit device.

FIG. 15 is a sectional view for describing a method of manufacturing this invention's circuit device.

FIG. 16 is a sectional view for describing a method of manufacturing this invention's circuit device.

FIG. 17 is a sectional view for describing a method of manufacturing this invention's circuit device.

FIG. 18 is a sectional view for describing a method of manufacturing this invention's circuit device.

FIG. 19 is a sectional view for describing a method of manufacturing this invention's circuit device.

FIG. 20 is a sectional view for describing a method of manufacturing this invention's circuit device.

FIG. 21(A) is a plan view, FIG. 21(B) is a sectional view, and FIG. 21(C) is a sectional view for describing this invention's circuit device.

FIG. 22 is a sectional view for describing a method of manufacturing this invention's circuit device.

FIG. 23 is a sectional view for describing a method of manufacturing this invention's circuit device.

FIG. 24 is a sectional view for describing a method of manufacturing this invention's circuit device.

FIG. 25 is a sectional view for describing a method of manufacturing this invention's circuit device.

FIG. 26 is a sectional view for describing a method of manufacturing this invention's circuit device.

FIG. 27(A) is a plan view, FIG. 27(B) is a sectional view, and FIG. 27(C) is a sectional view for describing this invention's circuit device.

FIG. 28 is a sectional view for describing a method of manufacturing this invention's circuit device.

FIG. 29 is a sectional view for describing a method of manufacturing this invention's circuit device.

FIG. 30 is a sectional view for describing a method of manufacturing this invention's circuit device.

FIG. 31 is a sectional view for describing a prior-art circuit device.

FIG. 32 is a sectional view for describing the prior-art circuit device.

### DETAILED DESCRIPTION OF THE PREFERRED EMBODIMENTS

(First Embodiment for Describing the Arrangement of a Circuit Device 10)

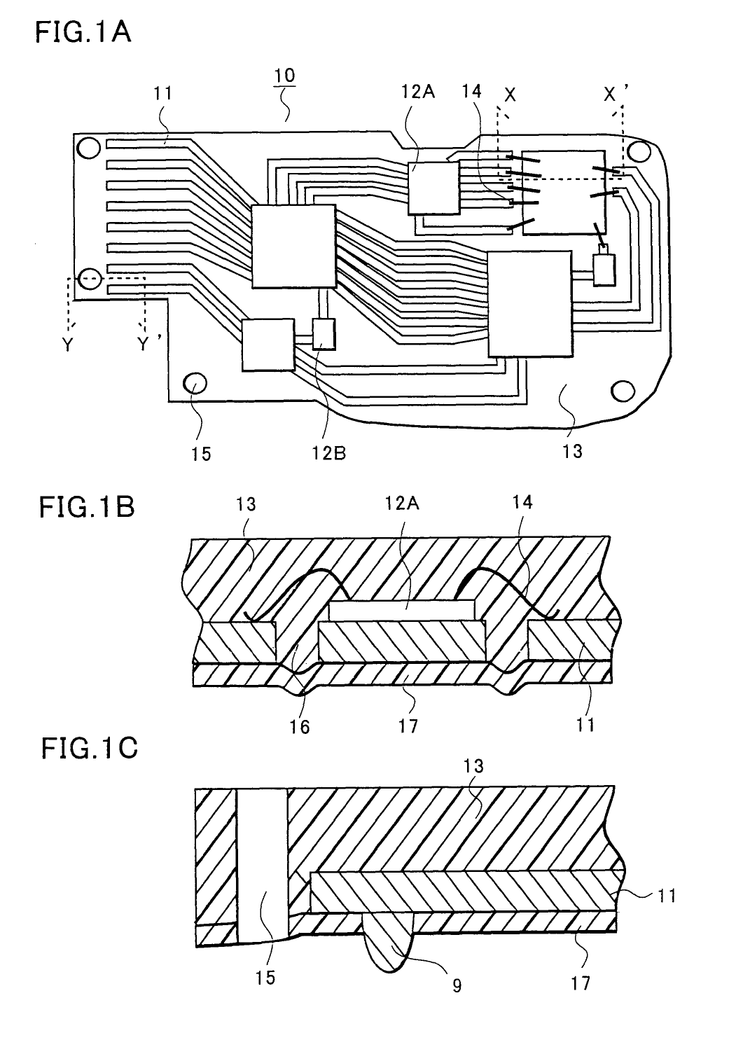

The arrangement, etc., of a circuit device 10 of this invention shall now be described with reference to FIG. 1. FIG. 1(A) is a plan view of circuit device 10, FIG. 1(B) is a sectional view along line X-X′ of FIG. 1(A), and FIG. 1(C) is a sectional view along line Y-Y′ of FIG. 1(A).

As shown in FIG. 1(A) and FIG. 1(B), circuit device 10 has the following arrangement. That is, circuit device 10 mainly comprises semiconductor elements 12A and chip elements 12B, which are circuit elements, conductive patterns 11 onto which semiconductor elements 12A and chip elements 12B are mounted, and an insulating resin 13, which covers circuit elements 12 and conductive patterns 11 while exposing the rear surfaces of conductive patterns 11 at the lower surface. The insulating resin 13 that is exposed from the rear surface of insulating resin 13 is covered by a resist 17, and on the rear surfaces of conductive patterns 11 that are exposed at openings of resist 17, external electrodes 9 are formed of brazing material, etc. Such components shall now be described.

Conductive patterns 11 are formed of copper foil or other metal and are embedded in insulating resin 13 with their rear surfaces exposed. Here, conductive patterns 11 form die pads and wiring onto which semiconductor elements 12A and chip elements 12B are mounted and furthermore form bonding pads onto which metal wires 14 are bonded. The rear surfaces of conductive patterns 11 that are exposed from the rear surface of insulating resin 13 are covered by resist 17, which is formed of resin. At desired locations of the rear surfaces of conductive patterns 11, external electrodes 9 for electrical input/output with the exterior are formed. Each conductive pattern 11 is electrically separated from other conductive patterns 11 by separation grooves 16 formed of insulating resin 13. Conductive patterns 11 are formed at regions except for the vicinities of the outer peripheral parts of circuit device 10.

Though in Fig. (A) several semiconductor elements 12A and chip elements 12B are mounted onto conductive patterns 11 and several conductive patterns 11 are connected to semiconductor elements 12A, in actuality, in an even larger number of conductive patterns 11 may be formed densely. Furthermore, though Fig. (B) shows a single layer of conductive patterns 11, a plurality of layers of conductive patterns 11 that are laminated across insulating layers may be formed as well.

Insulating resin 13 seals the ensemble while exposing the rear surfaces of conductive pattern 11. Here, insulating resin 13 seals the circuit elements, metal wires 14, and conductive patterns 11. As the material of insulating resin 13, a thermosetting resin formed by transfer molding or a thermoplastic resin formed by injection molding may be employed. As is clear from the Figures, insulating resin 13 forms the outer peripheral part of the entire device in a planar manner. The outer peripheral part of the device is partially formed in a curving manner and, at the corner parts, has parts that are formed to have an obtuse angle or an acute angle. Since the cutting of insulating resin 13 is performed with a laser with this invention, corner parts formed of insulating resin 13 can be formed to have an angle except for the right angle or to have a curved form. Also with regard to methods of forming insulating resin 13 besides the above methods, insulating resin 13 may be formed by potting, etc., as well.

Semiconductor elements 12A and chip elements 12B are circuit elements that are mounted onto conductive patterns 11. Here, each semiconductor element 12 is mounted face-down (flip chip bonding) or face-up, and in the case of face-up mounting, the electrodes of semiconductor element 12A and conductive patterns 11 are electrically connected by metal wires 14. Besides IC chips, transistor chips, diodes, and other active elements and chip resistors, chip capacitors, and other passive elements may be employed as circuit elements 12. Furthermore, a plurality of such active elements and passive elements may be positioned on conductive patterns 11. In a case where a semiconductor is mounted face-down, electrical connection is achieved via bumps formed on the semiconductor element.

Through-holes 15 shall now be described with reference to FIG. 1(A) and FIG. 1(C). Each through-hole 15 is formed by partially removing insulating resin 13 and passes through from the top surface to the rear surface of circuit device 10. Though a more detailed description shall be given later about a method of manufacturing the circuit device, through-hole 15 can be formed by a laser and is formed to have a planar section that is circular. By forming through-holes 15 at regions except for conductive patterns 11, the forming of through-holes 15 by a laser can be facilitated. Here, through-holes 15 are formed at peripheral parts of circuit device 10. Through-holes 15 are used as machine screw holes, etc., and by fixing by means of machine screws, circuit device 10 is fixed inside a frame of a set. Circuit device 10 may also be fixed inside a frame of a set by providing protrusions of sizes that fit in through-holes 15 in the interior of the frame and making the protrusions fit in through-holes 15.

(Second Embodiment for Describing a Method of Manufacturing Circuit Device 10)

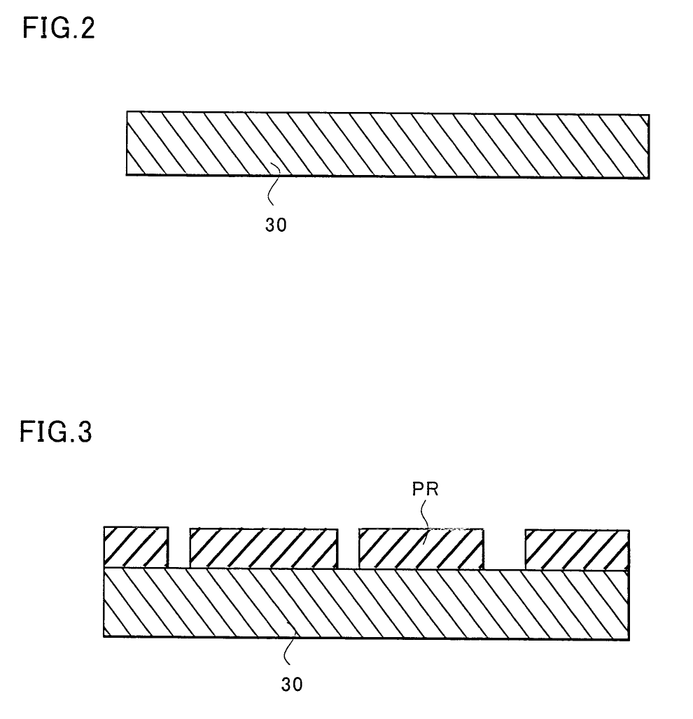

With the present embodiment, circuit device 10 is manufactured by the following steps. That is, circuit device 10 is manufactured by the steps of: forming, on a conductive foil 30, conductive patterns 11 constituting circuit devices 10 of the same type or different types; affixing circuit elements 12 onto conductive patterns 11; molding with insulating resin 13 so as to cover circuit elements 12; and using a laser to cut insulating resin 13 at locations of the outer peripheral part of each circuit device 10 that are in accordance with a desired shape to thereby perform separation into each of circuit devices 10. The respective steps of this invention shall now be described with reference to FIG. 2 to FIG. 10.

First Step: See FIG. 2 to FIG. 4.

This is the step of forming, on conductive foil 30, conductive patterns 11 constituting circuit devices 10 of the same type or different types. The conductive patterns may be formed, for example, by forming, in conductive foil 30, separation grooves 32 that are shallower than the thickness of conductive foil 30.

In this step, first, a sheet-like conductive foil 30 is prepared as shown in FIG. 2. The material of conductive foil 30 is selected in consideration of the adhesion of brazing material, bonding properties, and plating properties. A conductive foil having Cu as the principal material, a conductive foil having Al as the principal material, a conductive foil formed of Fe—Ni or other alloy, etc., can be used.

Though the thickness of conductive foil 30 is preferably approximately 10 μm to 300 μm in consideration of subsequent etching, basically, the thickness may be 300 μm or more or 10 μm or less. It is sufficient, as shall be described later, that it be possible to form separation grooves 32 that are shallower than the thickness of conductive foil 30.

The sheet-like conductive foil 30 may be wound and prepared in the form of a roll with a predetermined width, for example, of 45 mm and this may be conveyed to the respective steps described later, or a strip-shaped conductive foil 30, which has been cut to a predetermined size, may be prepared and this may be conveyed to the respective steps described later. Subsequently, the conductive patterns are formed.

First, as shown in FIG. 3, a photoresist PR is patterned on conductive foil 30 in a manner such that conductive foil 30 is exposed at regions except for the regions that are to become conductive patterns 11.

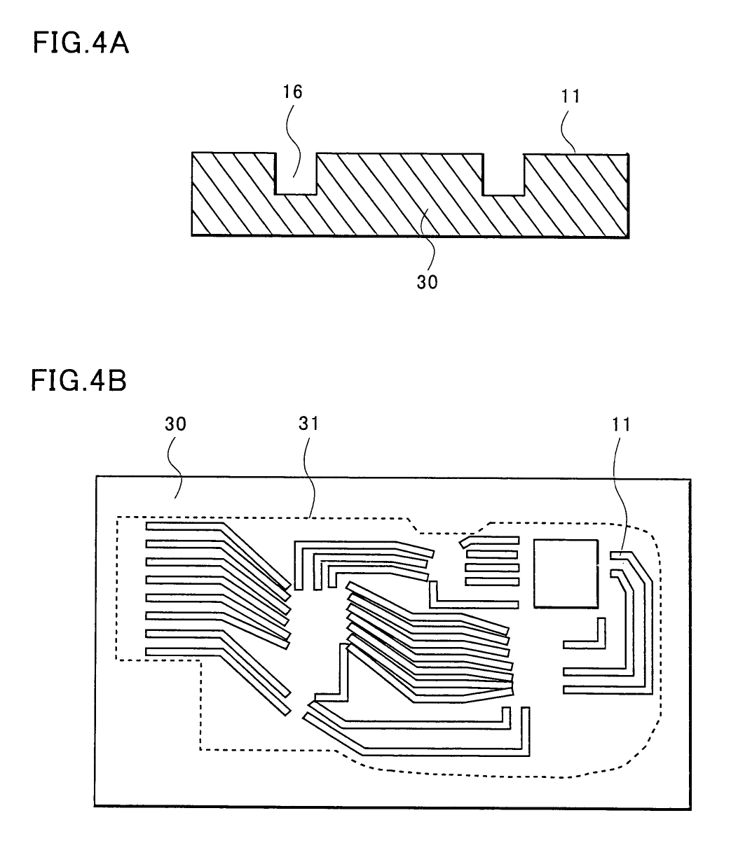

Then as shown in FIG. 4(A), by selective etching of conductive foil 30, separation grooves 16 of a predetermined depth are formed. Conductive patterns 11 are separated from each other by separation grooves 16 thus formed.

Concrete conductive patterns 11 shall now be described with reference to FIG. 4(B). Here, conductive patterns 11 form parts that are to be die pads, wiring, and bonding pads. In this Figure, the location of the outer peripheral part of the circuit device that is manufactured is indicated by dotted lines 31. Since circuit device 10 is separated using a laser to a shape indicated by dotted lines 31 in a subsequent step, conductive patterns 11 are not formed in regions of the locations indicated by dotted lines 31. In other words, separation grooves 16 are formed at regions indicated by dotted lines 31. Also, though several dozen conductive patterns 11 are illustrated in the Figure, an even greater number of conductive patterns 11 may be formed in actuality.

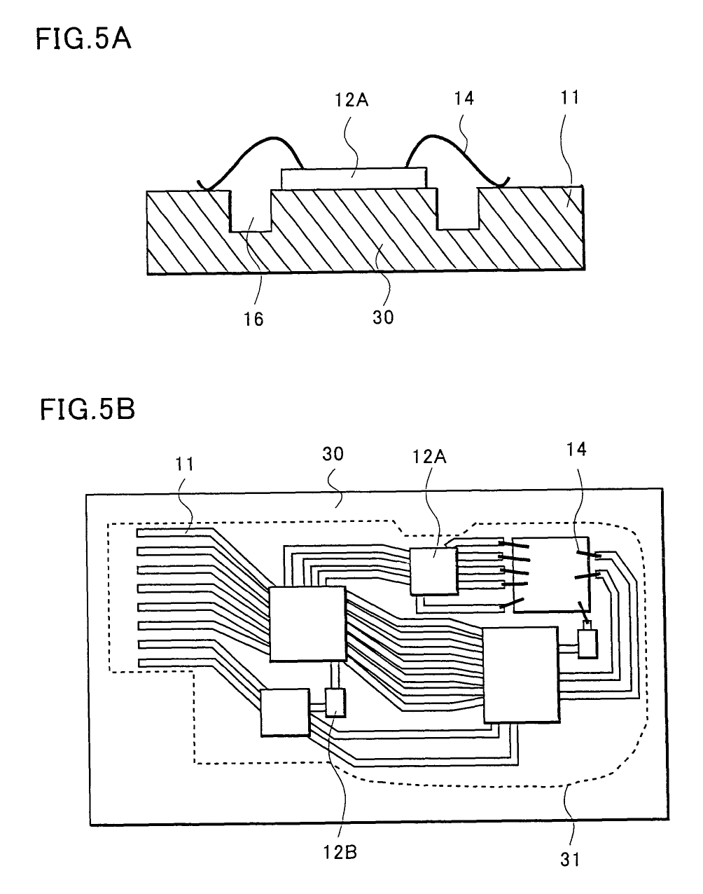

Second Step: See FIG. 5.

This step is a step of affixing and electrically connecting circuit elements 12 onto conductive patterns 11.

As shown in FIG. 5, circuit elements 12 are mounted via a brazing material onto conductive patterns 11. Here, as the brazing material, solder, Ag paste, or other conductive paste is used. Furthermore, the electrodes of semiconductor elements 12A are wire bonded with the desired conductive patterns 11. Concretely, the electrodes of circuit elements 12, mounted on conductive patterns 11, are batch wire bonded to desired conductive patterns 11 by ball bonding by hot pressing or wedge bonding by ultrasonic waves.

Though here, a single IC chip is affixed as a circuit element 12 to a conductive pattern 11, elements other than IC chips may be employed as circuit elements 12. Concretely, besides IC chips, transistor chips, diodes, and other active elements and chip resistors, chip capacitors, and other passive elements may be employed as circuit elements 12. Yet furthermore, a plurality of such active elements and passive elements may be positioned on conductive patterns 11.

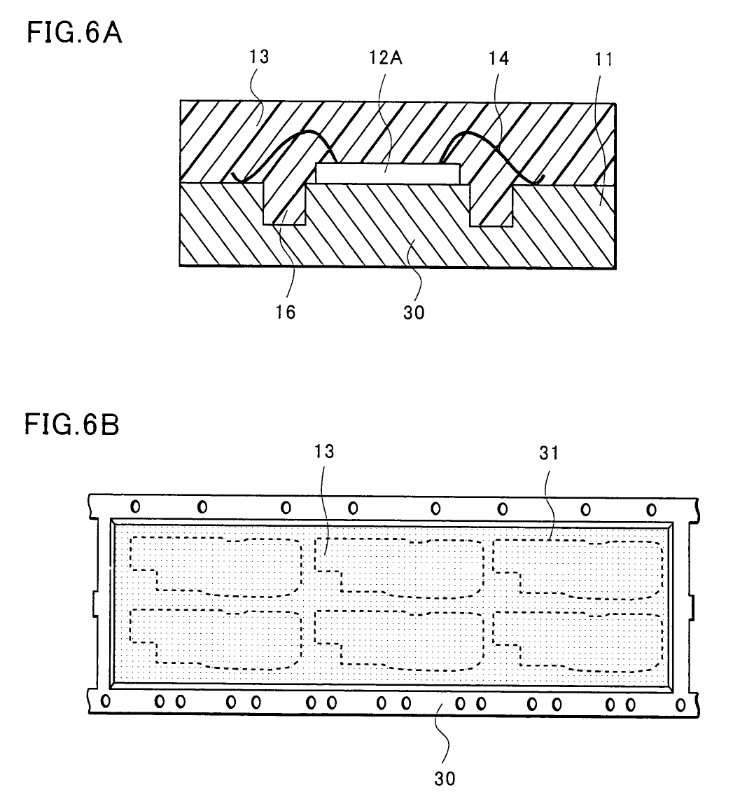

Third Step: See FIG. 6.

In this step, molding with insulating resin 13 is performed so as to cover circuit elements 12 and fill separation grooves 16.

As shown in FIG. 6(A), in this step, insulating resin 13 covers circuit elements 12 and the plurality of conductive patterns 11, and insulating resin 13 is filled in separation grooves 16 and thus strongly engages with separation grooves 32. Conductive patterns 11 are supported by insulating resin 13. This step can be accomplished by transfer molding, injection molding, or potting. With regard to the resin material, an epoxy resin or other thermosetting resin may be achieved by transfer molding, or a polyimide resin, polyphenylene sulfide, or other thermoplastic resin may be achieved by injection molding.

A characteristic of this step is that the conductive foil 30 that forms conductive patterns 11 serves as the supporting substrate until it is covered by insulating resin 13. Also, since separation grooves 16 are formed to be shallower than the thickness of the conductive foil, conductive foil 30 is not separated individually as conductive patterns 11. Conductive foil 30 can thus be handled integrally as a sheet-like foil and provides the characteristic that, in the process of molding insulating resin 13, the work of conveying to a mold and mounting in a mold are extremely facilitated.

As shown in FIG. 6(B), from insulating resin 13, which is formed integrally in the present step, six circuit devices 10 of the same type are formed. Here, the number of circuit devices 10 that are manufactured may be changed according to the size of circuit device 10. Also, a plurality of circuit devices 10 of different types, which differ in outer shape and in the electrical circuit that is arranged internally, may be formed.

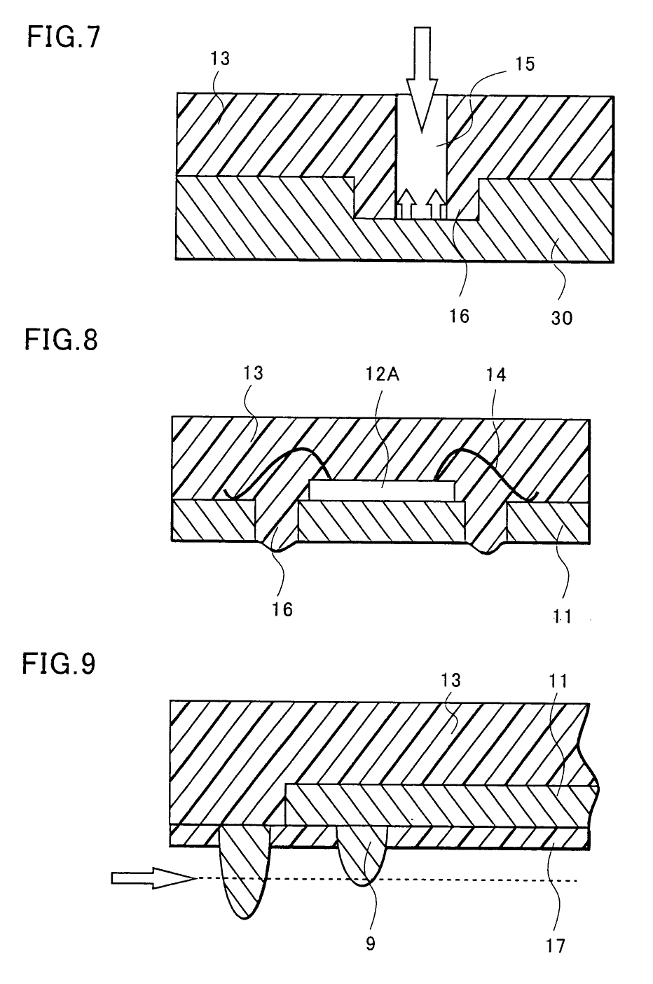

Fourth Step: See FIG. 7.

This step is a step of partially removing insulating resin 13 to form through-holes 15.

In this step, parts of insulating resin 13 are removed to form through-holes 15. Concretely, parts of insulating resin 13 are removed by a laser to form through-holes 20 and expose the top surface of conductive foil 30. Here, through-holes 15 are formed above the separation grooves and the surfaces of separation grooves 16 are exposed from through-holes 15. The laser used here is preferably a carbon dioxide laser.

Also in this Figure, the laser that is irradiated for the removal of insulating resin 13 is indicated by an arrow pointing downward. Insulating resin 30 is cut gradually by the laser and when the irradiation by the laser reaches the top surface of a separation groove 16, the laser is reflected by the top surface of separation groove 16. Since the reflected laser also has the function of cutting insulating resin 13, the side faces of each through-hole 15 is formed vertically. In the Figure, the components of the laser reflected by the top surface of separation groove 16 are indicated by the upward-pointing arrows. By thus making the laser be reflected by the top surface of conductive foil 30 and forming the side faces of through-holes 15 vertically, through-holes 15, which are to be used as machine screw holes, etc., can be improved in function. The intensity of the laser is set to a level at which insulating resin 13 is cut but conductive pattern 11 will not be cut. The through-holes 20 formed by the laser are formed to be circular in planar shape.

The conductive foil 30 at locations at which separation grooves 16 are formed is removed in a step of removing conductive foil 30 from the rear surface. Through-holes 15 are thus formed as holes passing through from the top surface to the rear surface of circuit device 10.

Also, though with the above description, through-holes 15 were formed above locations at which separation grooves 16 are formed, through-holes 15 may also be provided at locations at which separation grooves 16 are not formed. In this case, the intensity of the laser must be adjusted so that conductive foil 30 will be removed.

Sixth Step: See FIG. 8.

In this step, the rear surface of conductive foil 30 is removed until insulating resin 13 is exposed.

As shown in FIG. 8, in this step, the rear surface of conductive foil 30 is removed chemically and/or physically and separated as conductive patterns 11. This step is accomplished by polishing, grinding, etching, or metal vaporization by laser, etc. In an experiment, the entire surface of conductive foil 30 was wet etched to expose separation grooves 16 from insulating resin 13. As a result, conductive patterns 11 were separated from each other and a structure was provided with which the rear surfaces of conductive patterns 11 are exposed among insulating resin 13. A structure is thus provided with which the surface of insulating resin 13 that is filled in separation grooves 16 is substantially matched with the surfaces of conductive patterns 11.

Treatment of the rear surface of insulating resin 13 is then performed. Concretely, a resist 17 is formed to protect conductive patterns 11 that are exposed at the rear surfaces. External electrodes 9, formed of brazing material, etc., are then formed at desired locations.

In this step, the remaining thickness portions of conductive foil 30 at locations at which separation grooves 16 were formed is removed. Since the conductive foil 30 below through-holes 15 are thus removed, through-holes 15 become holes that are continuous from the top surface to the rear surface of circuit device 10.

Seventh Step: See FIG. 9.

In this step, external electrodes 9 are partially removed to make external electrodes 9 uniform in height.

The step of making external electrodes 9 uniform in height using a laser shall now be described with reference to FIG. 9. There will be some difference in the height of individual external electrodes 9, which are formed by screen printing, etc. Thus in this step, a laser is irradiated parallel to the surface direction of circuit device 10 to remove external electrodes 9 partially and make external electrodes 9 uniform in height. Since a laser propagates in a straight line, the tip of an external electrode 9 that is formed to a low height is slightly removed, and the tip of an external electrode 9 that has been formed to a comparatively large size is greatly removed.

By thus making external electrodes 9 uniform in height, electrical connections with external electrodes 9 can be assured.

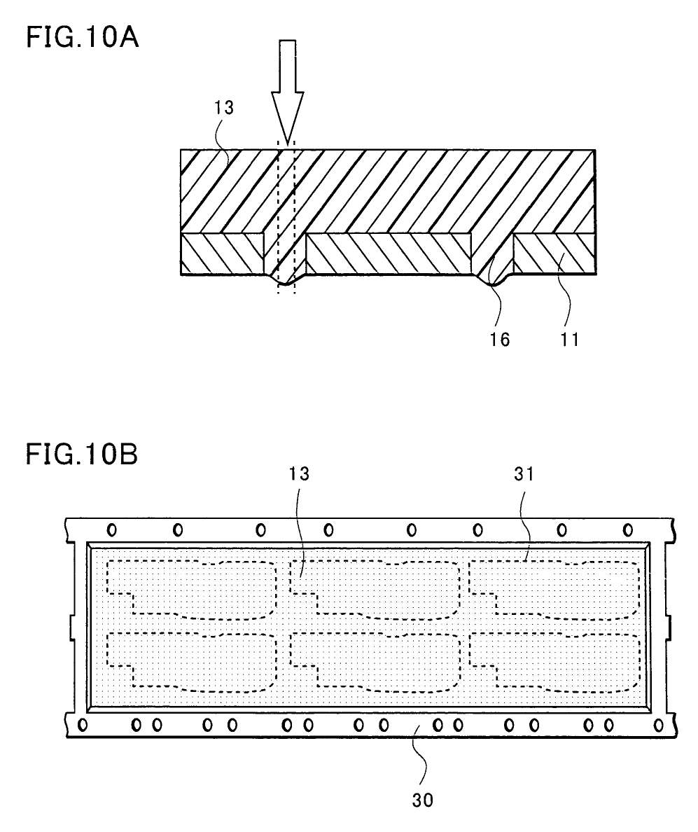

Step 8: See FIG. 10.

This step is a step of using a laser to cut insulating resin 13 at locations of the outer peripheral part of each circuit device 10 that are in accordance with a desired shape to thereby perform separation into each of circuit devices 10.

As shown in FIG. 10(A), in this step, insulating resin 13 is removed by a laser at parts that are formed only of insulating resin 13 in the thickness direction. Thus the laser removes only insulating resin 13 and the separation of conductive foil 30 is not performed here. The heat generated by performing removal by laser can thus be lessened. Thus even when circuit elements are disposed near outer peripheral parts of circuit device 10, damage of the circuit elements due to heat can be prevented since the heat generated in this step is low.

Here, an excimer laser or a carbon dioxide laser can be used as the laser for separating insulating resin 13. For example, separation of circuit devices 10 may be performed by using a carbon dioxide gas laser to perform separation of insulating resin 13 and using an excimer laser to eliminate the carbide formed in the process.

As shown in FIG. 10(B), a laser is used to remove insulating resin 13 at locations that are in accordance with the outer shape of each circuit device. The merits of separating circuit devices 10 using a laser in this manner are as follows. That is, with the separation of insulating resin 13 by a laser, the separated shape can be changed substantially freely by changing a drawing program software for controlling the laser. A circuit device 10 with a curved shape or other desired shape can thus be manufactured. Also, though with the above description, only insulating resin 13 is removed by a laser in the present step, conductive foil 30 may also be cut together by adjusting the intensity of the laser.

A circuit device 10, such as shown in FIG. 1 can be manufactured by the above-described steps.

(Third Embodiment for Describing Circuit Devices of Other Configurations)

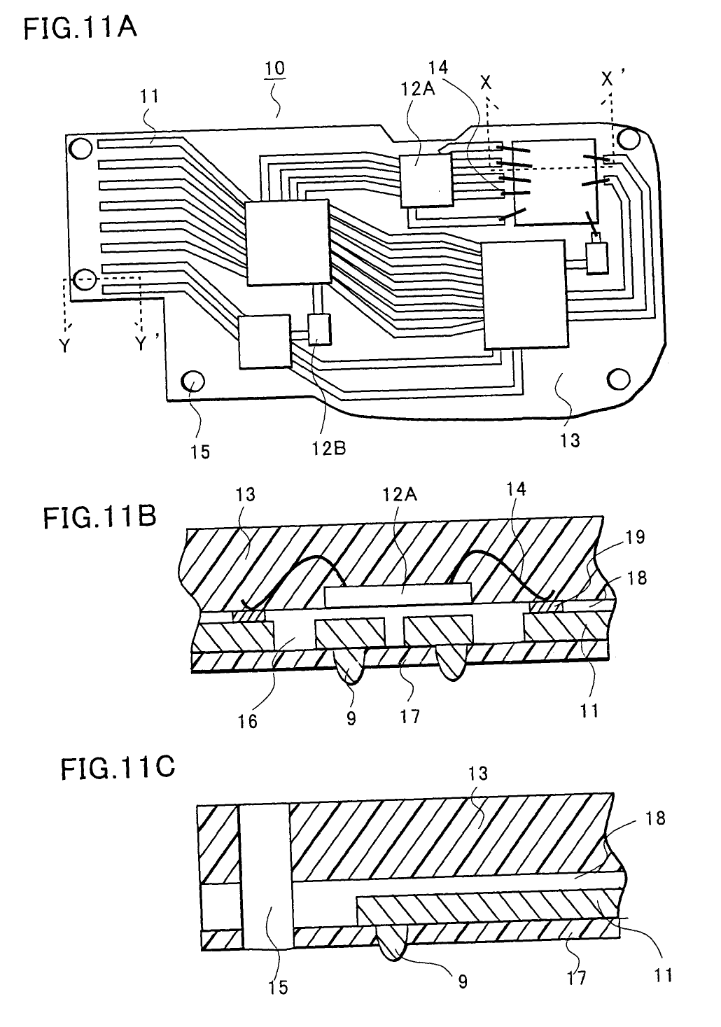

The arrangement and manufacturing methods of a circuit device 10 of another configuration shall now be described with reference to FIG. 11 to FIG. 20.

As shown in FIG. 11, circuit device 10 of another configuration mainly comprises semiconductor elements 12A and chip elements 12B, which are circuit elements, conductive patterns 11 onto which semiconductor elements 12A and chip elements 12B are mounted, and an insulating resin 13, which covers circuit elements 12 and conductive patterns 11 while exposing the rear surface of conductive patterns 11 at the lower surface. Conductive patterns 11 furthermore form wiring parts below semiconductor elements 12A. The insulating resin 13 that is exposed from the rear surface of insulating resin 13 is covered by a resist 17, and on the rear surfaces of conductive patterns 11 that are exposed at openings of resist 17, external electrodes 9 are formed of brazing material, etc.

Circuit device 10 of the present embodiment differs in the arrangement of conductive patterns 11 from circuit device 10 described in the first embodiment. That is, with circuit device 10 of the present embodiment, the conductive patterns form the wiring parts below semiconductor elements 12A as well. Due to this use of the parts below semiconductor elements 12A as wiring parts, the mounting density of the device as a whole can be improved and size reduction of the circuit device can be realized.

Manufacturing methods of circuit device 10 of this embodiment shall now be described. There are two methods by which circuit device 10 of this embodiment can be manufactured. In the first method, conductive patterns are formed from an insulated sheet with which two conductive films are laminated with an insulating layer in between. In the second method, conductive patterns are formed by forming separation grooves as in the second embodiment. These two methods of forming conductive patterns shall now be described. The steps except for the steps of forming the conductive patterns are the same as those of the above-described second embodiment. That is, the step of forming through-holes, the step of processing external electrodes, and the step of separating each circuit device by a laser are the same as those of the second embodiment.

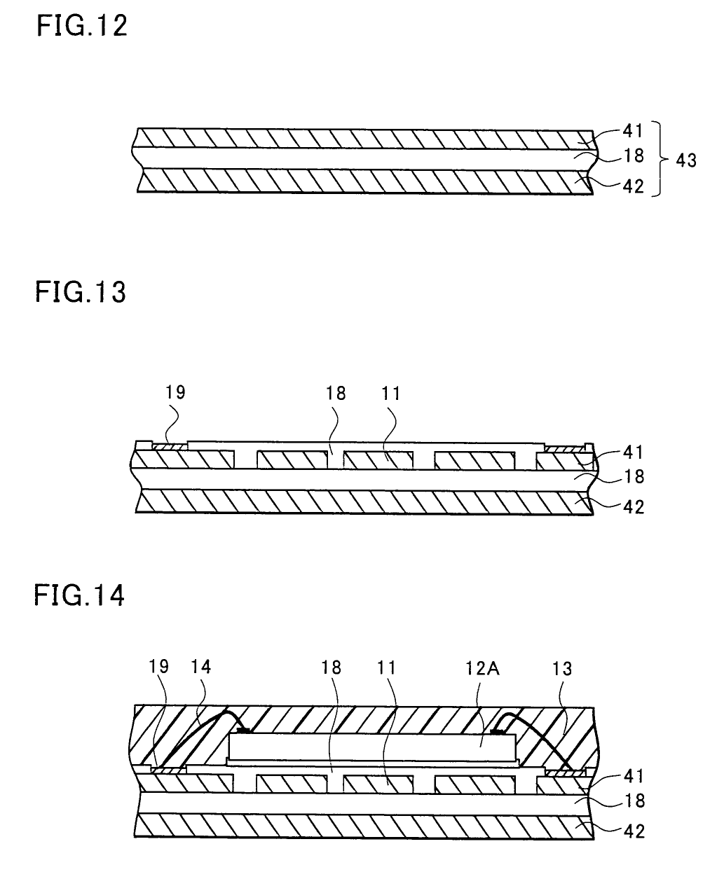

A manufacturing method of a circuit device that includes the first method of forming conductive patterns 11 from an insulated sheet 43 shall now be described with reference to FIG. 12 to FIG. 16.

Firstly, insulated sheet 43 is prepared as shown in FIG. 12. In this sheet, a first conductive film 41 and a second conductive film 42 are laminated with an insulating layer 18 in-between. First conductive film 41 becomes conductive patterns 11 and is formed thinly in order to form fine patterns. By contrast, second conductive film 42 has a function of supporting the ensemble until a step of performing molding and is thus required to have high strength and is formed to be thicker than first conductive film 41.

Conductive patterns 11 are formed and then conductive patterns 11 are covered by an insulating layer 18 as shown in FIG. 13. Concretely, conductive patterns 11 are formed by first performing selective etching of first conductive film 41. Conductive patterns 11 are then covered by an insulating layer 18. Insulating layer 18 is then removed partially to expose conductive patterns 11 at locations which will be bonding pads. This partial removal of insulating layer 18 can be performed using a laser. Plated films 19 are formed on the surfaces of the exposed conductive patterns 11.

As shown in FIG. 14, semiconductor elements 12A are affixed, electrically connected, and covered with an insulating resin 13. Concretely, semiconductor elements 12A are affixed onto insulating layer 18 using an insulating adhesive agent, etc. The electrodes of semiconductor elements 12A and the exposed parts of conductive patterns 11 are then electrically connected by metal wires 14. Semiconductor elements 12A and metal wires 14 are then sealed with insulating resin 13. This sealing may be carried out by transfer molding, injection molding, or potting, etc.

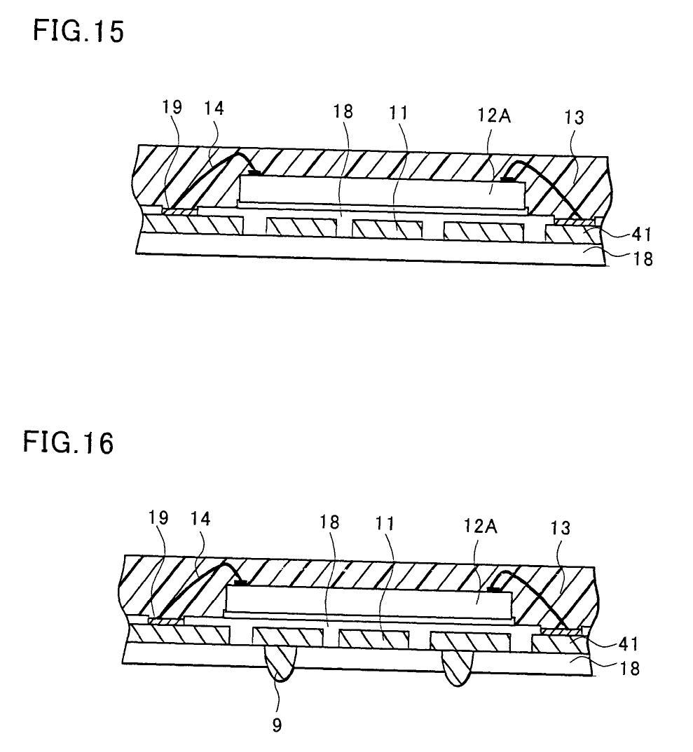

Second conductive film 42 is removed as shown in FIG. 15. Concretely, etching is performed from the rear surface to remove second conductive film 42 entirely. Insulating layer 18 thereby becomes exposed at the rear surface.

External electrodes 9 are formed on the rear surface as shown in FIG. 16. Concretely, first, insulating resin 18 is removed partially to form openings for forming external electrodes 9 in insulating layer 18. External electrodes 9 are then formed by coating the openings provided in insulating layer 18 with solder or other brazing material.

The second method of forming conductive patterns 11 shall now be described. With this method, conductive patterns 11 are formed from a single conductive foil 45 as in the second embodiment.

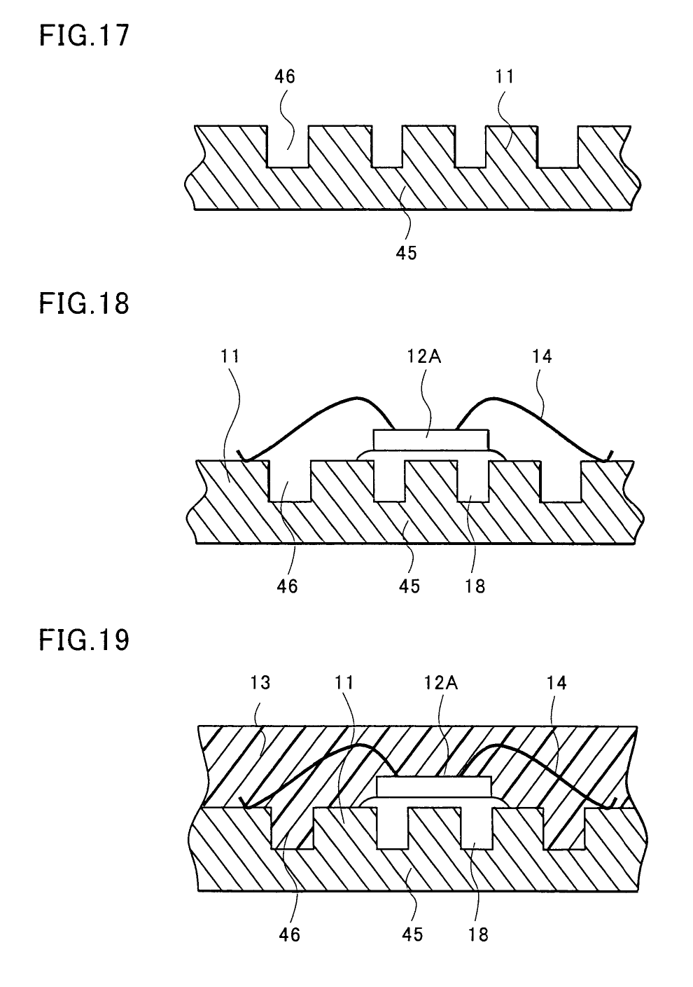

As shown in FIG. 17, after preparing conductive foil 45, separation grooves 46 are formed to form conductive patterns 11. Separation grooves 46 may be formed by selective etching.

As shown in FIG. 18, semiconductor elements 12A are affixed onto the upper parts of conductive patterns 11 using an insulating adhesive agent. Here, the insulating adhesive agent is also filled in the separation grooves positioned below semiconductor elements 12A. Furthermore, the electrodes of semiconductor elements 12A are electrically connected by metal wires to desired conductive patterns.

As shown in FIG. 19, semiconductor elements 12A and the metal wires are sealed with insulating resin 13. In this step, separation grooves 46 are also filled with insulating resin 13.

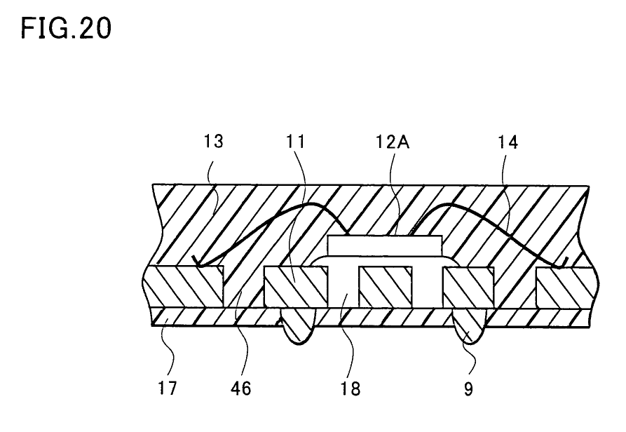

As shown in FIG. 20, conductive foil 45 is etched from the rear surface to expose insulating resin 13, filled in the separation grooves, at the rear surface. The individual conductive patterns 11 are thereby separated electrically. Conductive patterns 11, which are exposed at the rear surface, are protected by resist 17 and external electrodes 9 are formed at the desired locations.

(Fourth Embodiment for Describing a Circuit Device of Another Configuration)

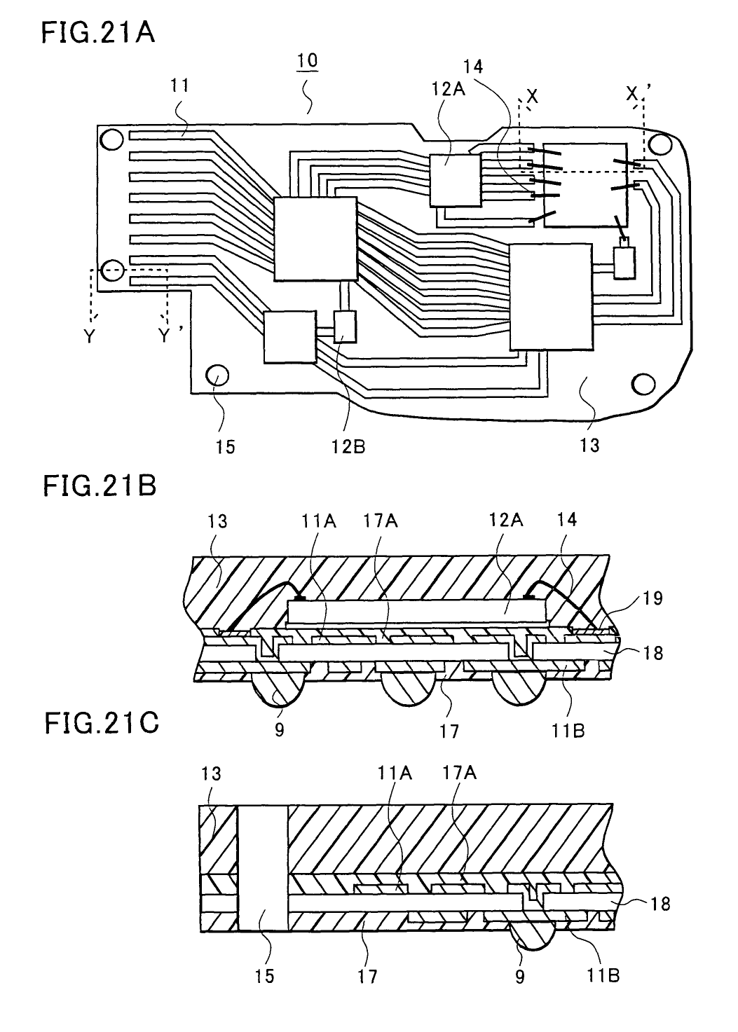

An arrangement and a manufacturing method of a circuit device 10 of another configuration shall now be described with reference to FIG. 21 to FIG. 26.

As shown in FIG. 21, circuit device 10 mainly comprises semiconductor elements 12A and chip elements 12B, which are circuit elements, conductive patterns 11 onto which semiconductor elements 12A and chip elements 12B are mounted, and an insulating resin 13, which covers circuit elements 12 and conductive patterns 11. Conductive patterns 11 furthermore have a multilayer wiring structure and comprise first conductive patterns 11A and second conductive patterns 11B. Second conductive patterns 11B are covered by a resist 17, and on the rear surfaces of second conductive patterns 11B that are exposed at openings of resist 17, external electrodes 9 are formed of brazing material, etc.

Circuit device 10 of the present embodiment differs in the arrangement of conductive patterns 11 from circuit device 10 described as the first embodiment. That is, with circuit device 10 of the present embodiment, the conductive patterns comprise first conductive patterns 11A and second conductive patterns 11B that are insulated from each other by an insulating layer 18. The conductive patterns thus form multilayer wiring and enable the realization of more complex wiring structures. A method of manufacturing circuit device 10 of this embodiment shall now be described. The steps except for the steps of forming the conductive patterns are the same as those of the above-described second embodiment. That is, the step of forming through-holes, the step of processing external electrodes, and the step of separating each circuit device by a laser are the same as those of the second embodiment. A concrete method of manufacturing circuit device 10 of this embodiment shall now be described.

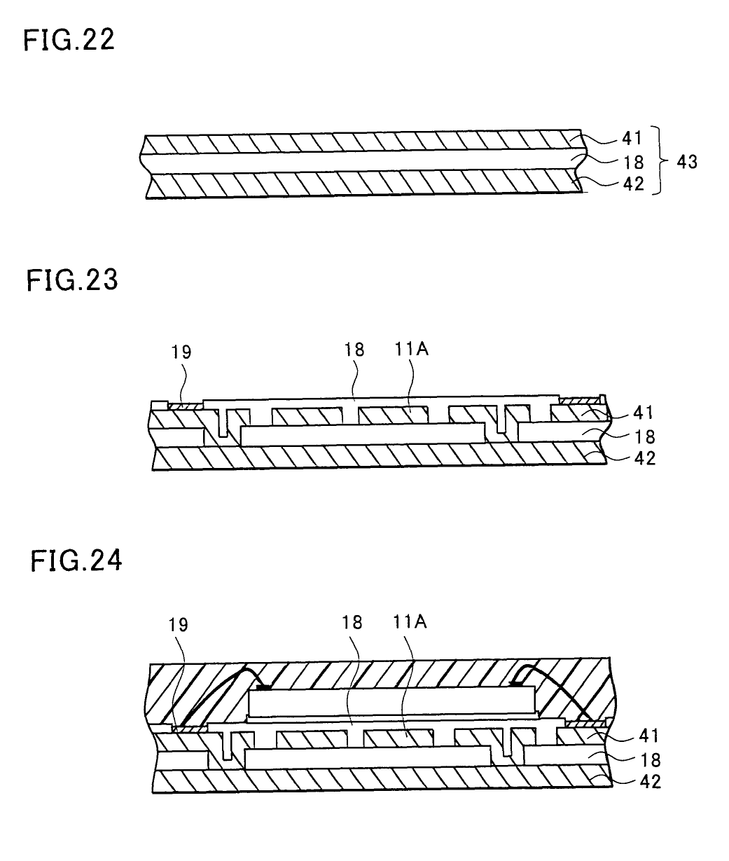

Firstly, an insulated sheet 43 is prepared as shown in FIG. 22. With this sheet, a first conductive film 41 and a second conductive film 42 are laminated with an insulating layer 18 in between. First conductive film 41 becomes first conductive patterns 11A and is formed thinly in order to form fine patterns. On the other hand, second conductive film 42 has a function of supporting the ensemble until a step of performing molding and is thus required to have a high strength and is formed to be thicker than first conductive film 41.

Conductive patterns 11 are formed and then conductive patterns 11 are covered by an insulating layer as shown in FIG. 23. Concretely, first conductive patterns 11A are formed by first performing selective etching of first conductive film 41. First conductive patterns 11A are then covered by an insulating layer 18. Insulating layer 18 is then removed partially to expose first conductive patterns 11 at locations which will be bonding pads. This partial removal of insulating layer 18 can be performed using a laser. Plated films 19 are formed on the surfaces of the exposed conductive patterns 11. Furthermore in this step, after partially removing insulating layer 18, plated films are formed to electrically connect first conductive patterns 11A with second conductive patterns 11B.

As shown in FIG. 24, semiconductor elements 12A are affixed, electrically connected, and covered with an insulating resin 13. Concretely, semiconductor elements 12A are affixed onto insulating layer 18 using an insulating adhesive agent, etc. The electrodes of semiconductor elements 12A and the exposed parts of first conductive patterns 11A are then electrically connected by metal wires 14. Semiconductor elements 12A and metal wires 14 are then sealed with insulating resin 13. This sealing may be carried out by transfer molding, injection molding, or potting, etc.

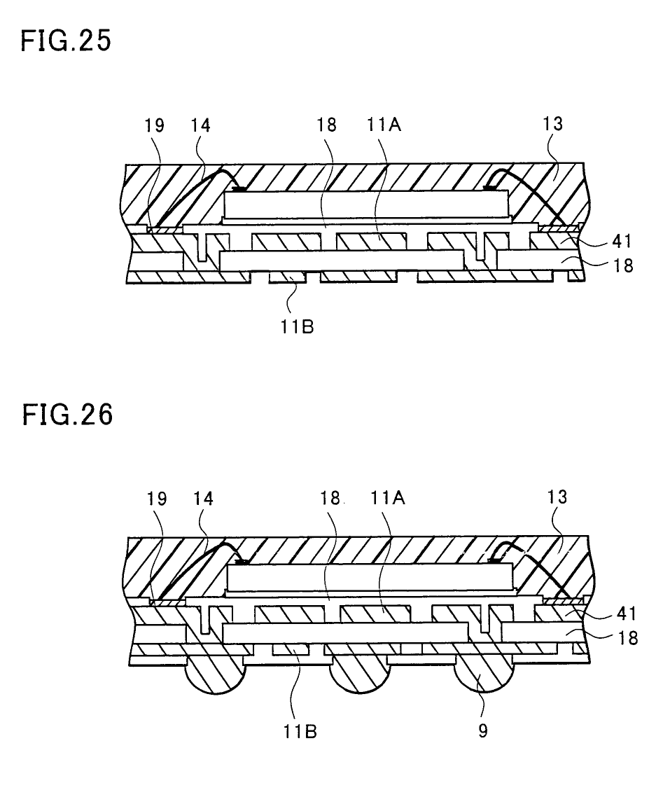

The second conductive patterns are then removed partially from the rear surface to form second conductive patterns 11B as shown in FIG. 25. Second conductive patterns 11B form the pads for forming wiring parts and external electrodes. Lastly, external electrodes 9 are formed on the rear surface of second conductive patterns 11B as shown in FIG. 26.

(Fifth Embodiment for Describing a Circuit Device of Another Configuration)

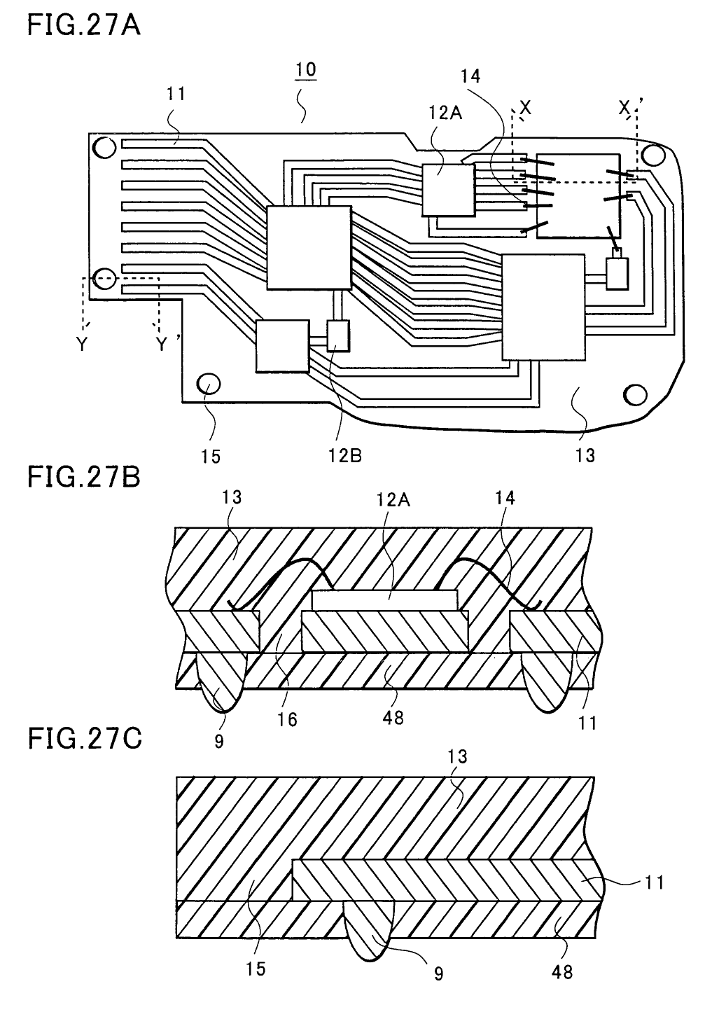

The arrangement and a method of manufacture of a circuit device 10 of another configuration shall now be described with reference to FIG. 27 to FIG. 30.

As shown in FIG. 27, circuit device 10 mainly comprises semiconductor elements 12A and chip elements 12B, which are circuit elements, conductive patterns 11 onto which semiconductor elements 12A and chip elements 12B are mounted, a flexible sheet 48, on the top surface of which conductive patterns 11 are formed, and an insulating resin 13, which covers circuit elements 12 and conductive patterns 11. On the rear surfaces of conductive patterns 11, external electrodes 9 are formed of brazing material, etc.

Circuit device 10 of the present embodiment differs from circuit device 10 described in the first embodiment in that conductive patterns 11 are formed on the top surface of flexible sheet 48.

A method of manufacturing circuit device 10 of this embodiment shall now be described. The steps except for the steps of forming the conductive patterns are the same as those of the above-described second embodiment. That is, the step of forming through-holes, the step of processing external electrodes, and the step of separating each circuit device by a laser are the same as those of the second embodiment.

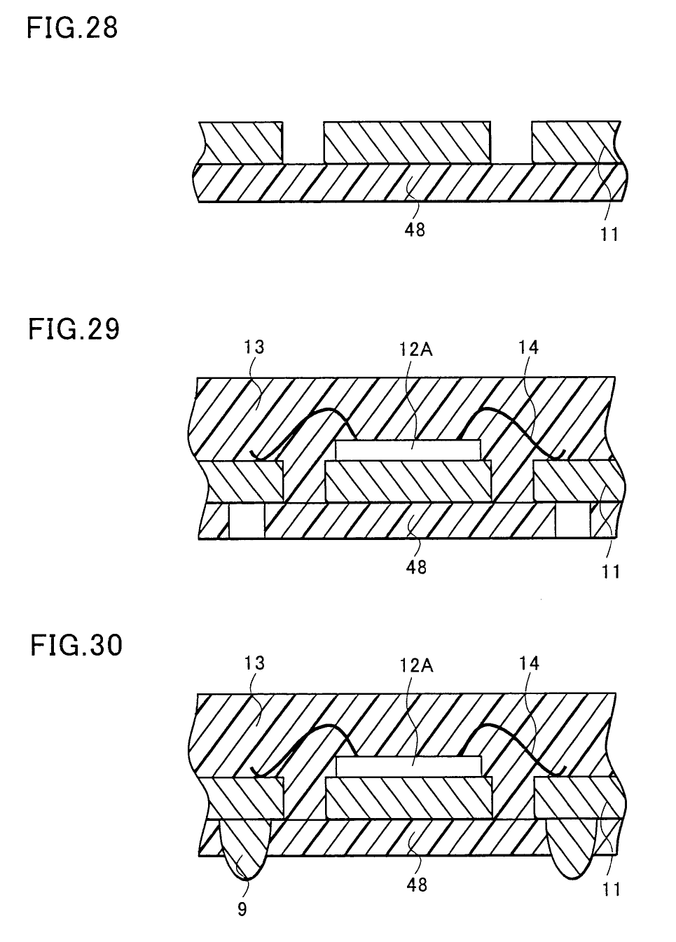

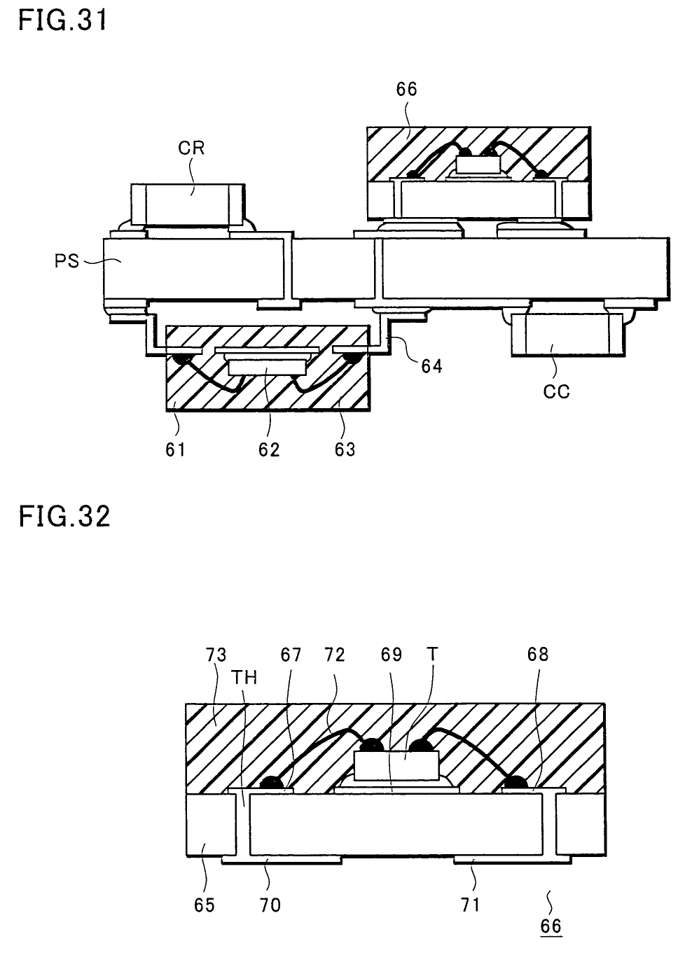

Conductive patterns 11 are formed on the top surface of flexible sheet 48 as shown in FIG. 28. Next, as shown in FIG. 29, semiconductor elements 12A are affixed to die pads formed of conductive patterns 11 and then the electrodes of semiconductor elements 12A and conductive patterns 11 are connected electrically. Semiconductor elements 12A, metal wires 14, and conductive patterns 11 are then sealed in an insulating layer 18. Lastly, as shown in FIG. 30, desired locations of flexible sheet 48 are removed partially and external electrodes 9 are formed at these locations after exposing the rear surfaces of conductive patterns 11.

What is claimed is:

1. A circuit device comprising: circuit elements; conductive patterns, to which said circuit elements are affixed and forming wiring; and an insulating resin, sealing said circuit elements and said conductive patterns; wherein
side face of said insulating resin is cut by a laser.

2. The circuit device as set forth in claim 1, wherein an outer peripheral part formed of said insulating resin is curved.

3. The circuit device as set forth in claim 1, wherein corner parts of an outer peripheral part formed of said insulating resin are formed to have an acute angle or an obtuse angle.

4. A circuit device manufacturing method comprising the steps of:
forming, on a conductive foil, conductive patterns constituting circuit devices of the same type or different types;
affixing circuit elements onto said conductive patterns;
molding with insulating resin so as to cover said circuit elements; and
using a laser to cut said insulating resin at locations of the outer peripheral part of each circuit device that are in accordance with a desired shape to thereby perform separation into each of said circuit devices.

5. A circuit device manufacturing method comprising the steps of:
forming separation grooves, which are shallower than the thickness of said conductive foil, at regions of the conductive foil except for regions that are to be conductive patterns constituting circuit devices of the same type or different types;
affixing circuit elements onto said conductive patterns;
molding with insulating resin so as to cover said circuit elements and fill said separation grooves;
removing said rear surface of said conductive foil until said insulating resin is exposed; and
using a laser to cut said insulating resin at locations of the outer peripheral part of each circuit device that are in accordance with a desired shape to thereby perform separation into each of said circuit devices.

6. The circuit device manufacturing method as set forth in claim 4 or 5, wherein said laser is used to remove only said insulating resin.

7. The circuit device manufacturing method as set forth in claim 4 or 5, wherein a carbon dioxide laser is used to remove said insulating resin.

8. The circuit device manufacturing method as set forth in claim 4 or 5, wherein said conductive patterns form die pads, bonding pads, and wiring.

9. The circuit device as set forth in claim 4 or 5, wherein an outer peripheral part formed of said insulating resin is formed in a curving manner.

10. The circuit device as set forth in claim 4 or 5, wherein corner parts of an outer peripheral part formed of said insulating resin are formed to have an acute angle or an obtuse angle.

11. A circuit device manufacturing method comprising the steps of:
forming, on regions of a conductive foil, conductive patterns constituting at least one circuit device;
affixing circuit elements onto said conductive patterns;
molding with insulating resin so as to cover said circuit elements;
forming through-holes in said insulating resin; and
separating into individual circuit devices.

12. A circuit device manufacturing method comprising the steps of:
forming separation grooves, which are shallower than the thickness of said conductive foil at regions of the conductive foil except for regions that are to be conductive patterns constituting at least one circuit device;
affixing circuit elements onto said conductive patterns;
molding with insulating resin so as to cover said circuit elements and fill said separation grooves;
forming through-holes in said insulating resin so as to partially expose said separation grooves;
removing the remaining thickness portions of said conductive foil at locations at which said separation grooves are formed to expose said insulating resin filled in said separation groove and said through-holes; and
separating into individual circuit devices.

13. The circuit device manufacturing method as set forth in claim 11 or 12, wherein a laser is used to form said through-holes.

14. The circuit device manufacturing method as set forth in claim 11 or 12, wherein said laser is reflected by the surfaces of said separation grooves and the side faces of said through-holes are formed vertically.

15. A method of manufacturing a circuit device with which a plurality of external electrodes formed of brazing material are formed on a rear surface, wherein the height of said external electrodes are made uniform by irradiation of a laser in the surface direction of said circuit device.
